(19) United States
(12) Patent Application Publication
(10) Pub. No.: US 2014/0312387 A1
(43) Pub. Date: Oct. 23, 2014

(54) SEMICONDUCTOR DEVICE AND METHOD FOR FABRICATING THE SAME

(71) Applicant: SAMSUNG ELECTRONICS CO., LTD., Suwon-Si (KR)

(72) Inventor: JU-YOUN KIM, SUWON-SI (KR)

(73) Assignee: SAMSUNG ELECTRONICS CO., LTD., Suwon-Si (KR)

(21) Appl. No.: 14/101,381

(22) Filed: Dec. 10, 2013

(30) Foreign Application Priority Data
Apr. 23, 2013 (KR) 10-2013-0045031

(51) Int. Cl. H01L 29/267; H01L 27/092; H01L 29/78

(52) U.S. Cl. CPC H01L 29/267; H01L 29/78; H01L 27/092
USPC 257/192

(57) ABSTRACT

A semiconductor device includes a base layer of a group III-V compound, a channel layer disposed on the base layer and including a group IV element, a nitride layer disposed on the channel layer, a gate insulation layer disposed on the nitride layer and a gate electrode disposed on the gate insulation layer. The concentration of nitrogen atoms existing at a first interface between the nitride layer and the gate insulation layer is higher than that existing at a second interface between the nitride layer and the channel layer.

### PRIORITY STATEMENT

This application claims priority from Korean Patent Application No. 10-2013-0045031 filed on Apr. 23, 2013 in the Korean Intellectual Property Office, and all the benefits accruing therefrom under 35 U.S.C. 119, the entire contents of which are hereby incorporated by reference.

### BACKGROUND

1. Technical Field

The inventive concept relates to a semiconductor device and to a method of fabricating the same. More particularly, the inventive concept relates to a transistor having a channel region including a group III-V compound and a gate insulation layer disposed on the channel region, and to a method of fabricating the same.

2. Description of the Related Art

Using a group III-V compound to form a channel of a transistor is currently under consideration as a means to improve carrier mobility in the channel.

However, if a gate insulation layer of a high-k dielectric material is directly formed on a group III-V compound, gate leakage current or other undesirable effects which lower transistor performance may occur.

### SUMMARY

According to an aspect of the present invention, there is provided a semiconductor device comprising a base layer of a compound of elements each being a group III or V element, a channel layer disposed on the base layer and including a group IV element, a nitride layer disposed on the channel layer, a gate insulation layer disposed on the nitride layer, and a gate electrode disposed on the gate insulation layer, and in which the concentration of nitrogen atoms existing at a first interface between the nitride layer and the gate insulation layer is higher than that existing at a second interface between the nitride layer and the channel layer.

According to another aspect of the present invention, there is provided a semiconductor device comprising a base layer having a first region and a second region and comprising a compound of elements each being a group III or V element, at least one first buffer layer disposed on the first region of the base layer and comprising a first channel layer, at least one second buffer layer disposed on the second region of the base layer and comprising a second channel layer, a high-k material layer disposed on the first and second buffer layers, and a gate electrode disposed on the high-k material layer, and in which the first channel layer comprises a group IV element, the second channel layer is of a compound including a group IV element, and the second channel layer has a composition different from that of the first channel layer.

According to still another aspect of the inventive concept, there is provided a semiconductor device comprising a base of a compound of elements each being a group III or V element, a channel layer contacting the base and including a group IV element, a gate insulation layer of high-k material disposed on the channel layer, an interface layer contacting the channel layer, whereby the interface layer is interposed between the channel layer and the gate insulation layer, and a gate electrode disposed on the gate insulation layer, and in which an interface between the interface layer and the channel layer is substantially free of nitrogen atoms.

### BRIEF DESCRIPTION OF THE DRAWINGS

The above and other features and advantages of the inventive concept will become more apparent from the following detailed description of the preferred embodiments thereof made with reference to the attached drawings in which:

FIG. 1 is a cross-sectional view of an embodiment of a semiconductor device according to the inventive concept;

FIG. 2 is a graph illustrating nitrogen concentration throughout an interface layer of a gate of the device shown in FIG. 1;

FIG. 3 is a cross-sectional view of another embodiment of a semiconductor device according to the inventive concept;

FIG. 4 is a graph illustrating nitrogen concentration throughout an interface layer of a gate of the device shown in FIG. 3;

FIG. 5 is a cross-sectional view of still another embodiment of a semiconductor device according to the inventive concept;

FIG. 6 is a cross-sectional view of still another embodiment of a semiconductor device according to the inventive concept;

FIG. 7 is a cross-sectional view taken along line A-A′ of FIG. 6;

FIG. 8 is a cross-sectional view taken along line B-B′ of FIG. 7;

FIGS. 9 and 10 are a circuit diagram and a plan view of the layout of still another embodiment of a semiconductor device according to the inventive concept

FIG. 11 is a block diagram of an electronic system including a semiconductor device according to the inventive concept;

FIG. 12 is a plan view and FIG. 13 is a front view of electronic products that may employ semiconductor devices according to the inventive concept; and

FIGS. 14, 15, 16 and 17 are cross-sectional views of a semiconductor device during the course of its manufacture and together illustrate a method of fabricating a semiconductor device according to the inventive concept.

### DETAILED DESCRIPTION OF THE PREFERRED EMBODIMENTS

Various embodiments and examples of embodiments of the inventive concept will be described more fully hereinafter with reference to the accompanying drawings. In the drawings, the sizes and relative sizes and shapes of elements, layers and regions, such as implanted regions, shown in section may be exaggerated for clarity. In particular, the cross-sectional illustrations of the semiconductor devices and intermediate structures fabricated during the course of their manufacture are schematic. Also, like numerals are used to designate like elements throughout the drawings.

It will also be understood that when an element or layer is referred to as being disposed “on” or “connected to” another element or layer, it can be directly on or directly connected to the other element or layer or intervening elements or layers may be present. In contrast, when an element or layer is referred to as being disposed “directly on” or in contact with another element or layer, there are no intervening elements or layers present.

Furthermore, spatially relative terms, such as “top” are used to describe an element's and/or feature's relationship to another element(s) and/or feature(s) as illustrated in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the inventive concept can assume orientations different than those illustrated in the drawings when in use.

It will be understood that although the terms first and second are used herein to describe various elements, regions, layers, etc., these elements, regions, and/or layers are not limited by these terms. These terms are only used to distinguish one element, layer or region from another.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. The term “group” as used in the phrase “group IV element” will obviously be referring to the Group of the Periodic Table of Elements.

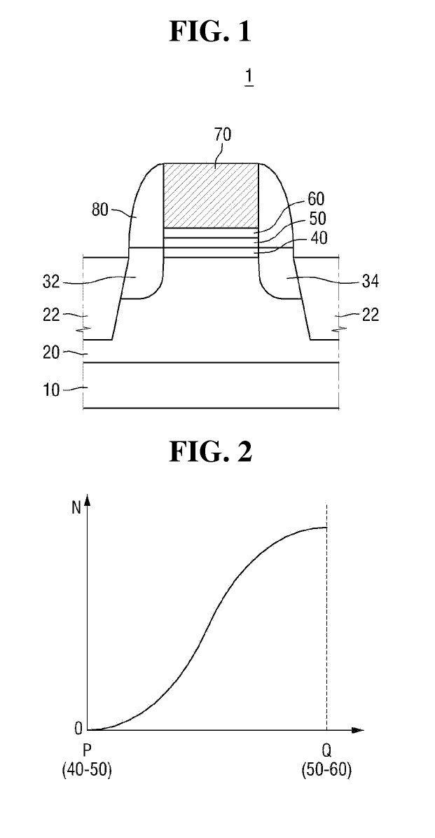

An embodiment of a semiconductor device according to the inventive concept will now be described with reference to FIGS. 1 and 2.

The semiconductor device 1 includes a base layer 20, buffer layers 40 and 50, a gate insulation layer 60, and a gate electrode 70.

The base layer 20 may be formed on a substrate 10. In this case, the substrate 10 may be of at least one semiconductor material selected from the group consisting of Si, Ge, SiGe, GaP, GaAs, SiC and SiGeC. Alternatively, the substrate 10 may be a silicon on insulator (SOI) substrate.

The base layer 20 formed on the substrate 10 provides the channel region of a transistor. The base layer 20 may be of a compound of elements selected from groups III, or V of the Periodic Table (referred to hereinafter as a group III-V compound). Examples of group III-V compounds include gallium arsenide (GaAs), gallium phosphide (GaP), indium arsenide (InAs), indium phosphide (InP), indium gallium arsenide (InGaAs), and indium gallium phosphide (InGaP). Such a base layer 20 of a group III-V compound will allow for excellent carrier mobility in the channel region.

Also, the base layer 20 may be an epi layer. That is to say, the base layer 20 may be formed on the substrate 10 by epitaxial growth. An isolation layer 22, such as a shallow trench isolation (STI) layer, may be formed in the base layer 20 to define a channel region.

Note, also, although FIG. 1 illustrates an embodiment in which the substrate 10 and the base layer 20 are discrete, the base layer 20 does not have to be a layer that is discrete from the substrate 10. That is, the base layer 20 including a group III-V compound and providing the channel region may be considered as or constitute the substrate of the device. Thus, although the term “base layer” may be used in the following, the term need not necessarily refer to a layer that is formed on an underlying substrate, but may refer to the base or substrate of the device itself.

The buffer layers 40 and 50 are formed on the group III-V compound, e.g., are be formed on the base layer 20. The buffer layers 40 and 50 prevent contact between the gate insulation layer 60 and the base layer 20. In particular, in the case in which the gate insulation layer 60 is of a high-k material, the buffer layers 40 and 50 minimize a gate leakage current, which would otherwise occur due to contact between the high-k material of the gate insulation layer 60 and the group III-V compound of the base layer 20.

The buffer layers 40 and 50 will be referred to hereinafter as a channel layer 40 and an interface layer 50.

The channel layer 40 in this embodiment includes a group IV element, meaning that the channel layer 40 may consist of a group IV element or may be of a compound having a group IV element. For example, the channel layer 40 may consist of Si or SiGe. The channel layer 40 may provide the channel region of the semiconductor device 1 alone or in combination with some of the base layer 20. Meanwhile, the channel layer 40 may be subjected to stress applied from the base layer 20 because the materials forming the base layer 20 and the material forming the channel layer 40 are different from each other. Therefore, the channel layer 40 may provide a strained channel of the semiconductor device 1.

The channel layer 40 may be an epi layer. That is, the channel layer 40 may be formed on the base layer 20 by epitaxial growth. Moreover, the channel layer 40 may be relatively thin so as to prevent defects from being generated in the channel layer 40 due to the stress applied from the base layer 20.

The interface layer 50 obviates a defective interface between the channel layer 40 and the gate insulation layer 60. The interface layer 50 may be of a low-k material, i.e., a material having a dielectric constant (k) of 9 or less. For example, the interface layer 50 may be a silicon oxide layer (k≈4) or a silicon oxynitride layer (k≈4˜8 according to the contents of oxygen and nitrogen atoms). Alternatively, the interface layer 50 may be made of silicate, or a laminate of a combination of the materials listed above.

In a preferred embodiment, the interface layer 50 is formed of silicon oxynitride layer (SiON). In this case, the concentration of nitrogen atoms existing at the top of the interface layer 50 may be relatively high, while the concentration of nitrogen atoms existing at the bottom of the interface layer 50 may be relatively low.

In more detail, referring to FIG. 2, the concentration of nitrogen atoms existing at a first interface Q between the interface layer 50 and the gate insulation layer 60 is higher than that existing at a second interface P between the interface layer 50 and the channel layer 40. Furthermore, the concentration of nitrogen atoms in the interface layer 50 may gradually decrease away from the first interface Q toward the second interface P. In addition, most of the nitrogen atoms may be present at a region near and including the first interface Q between the interface layer 50 and the gate insulation layer 60 but the region near and including the second interface P between the interface layer 50 and the channel layer 40 may be substantially devoid of nitrogen atoms.

If, on the other hand, i.e., contrary to an aspect of the inventive concept, the concentration of nitrogen atoms existing at the second interface P were higher than that existing at the first interface Q or other regions of the interface layer 50, the nitrogen atoms around the second interface P could deteriorate interface characteristics between the interface layer 50 and the channel layer 40, thereby lowering the performance of the semiconductor device 1.

Referring back to FIG. 1, a source 32 and a drain 34 may be formed at opposite sides of the buffer layers 40 and 50. In the illustrated embodiment, the source 32 and the drain 34 overlap the channel layer 40 and the base layer 20 in the vertical direction. In this respect, the source 32 and the drain 34 may be formed by injecting impurities into regions on the channel layer 40 and the base layer 20.

The gate insulation layer 60 is disposed on the buffer layers 40 and 50. The gate insulation layer 60 may include a high-k material. For example, the gate insulation layer 60 may be of a material selected from the group consisting of HfO₂, ZrO₂, Ta₂O₅, TiO₂, SrTiO₃, BaTiO₃, and SrTiO₃. Moreover, the thickness of the gate insulation layer 60 depends on its material and the type of the semiconductor device 1. For example, if the gate insulation layer 60 is of HfO₂, it is formed to a thickness of approximately 50 Å or less (specifically approximately 5 to 50 Å) depending on the type of the semiconductor device 1.

A gate electrode 70 is disposed on the gate insulation layer 60. Although not shown, the gate electrode 70 may include at least one work function adjusting layer and a gate metal layer formed on the at least one work function adjusting layer. The work function adjusting layer is used to adjust a work function of the semiconductor device 1. The gate metal layer may include Al or W. If the gate metal layer includes Al, a barrier layer for preventing Al from penetrating into the underlying gate insulation layer 60 is formed on the work function adjusting layer before the gate metal layer is formed.

As is also shown, a spacer 80 may be disposed on both sidewalls of the gate electrode 70. The spacer 80 may include at least one of a nitride layer and an oxynitride layer. In addition, the spacer 80 may have an L-shaped cross section unlike that of the spacer shown in the figure but known per se.

As described above, in the semiconductor device 1 according to the inventive concept, the gate insulation layer 60 formed of a high-k material does not contact the base layer 20 formed of a group III-V compound; rather, buffer layers consisting of the channel layer 40 and the interface layer 50 are provided therebetween. Thus, gate leakage current can be minimized, thereby preventing characteristics of the semiconductor device 1 from being lowered.

Furthermore, the interface layer 50 may be formed of, for example, a nitride layer to improve the region between the gate insulation layer 60 and the channel layer 40. In this case, the concentration of nitrogen atoms existing at the first interface Q between the interface layer 50 and the gate insulation layer 60 is higher than that existing at the second interface P between the interface layer 50 and the channel layer 40. Accordingly, the reliability of the semiconductor device 1 is improved.

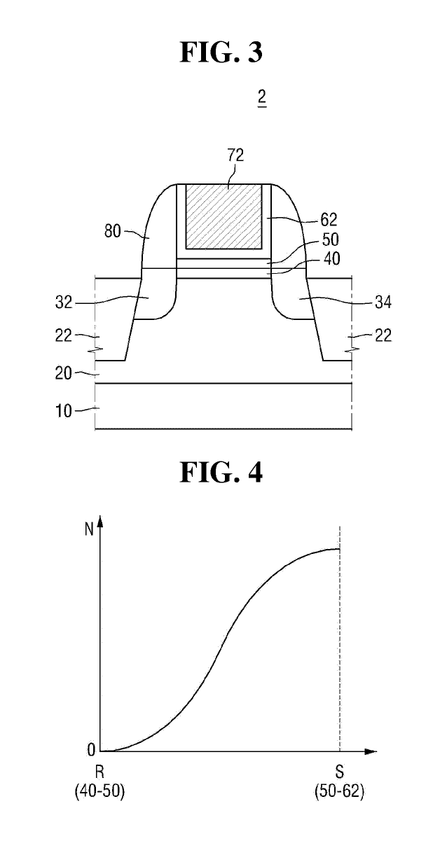

Next, another embodiment of a semiconductor device according to the inventive concept will be described with reference to FIGS. 3 and 4.

Referring to FIG. 3, the semiconductor device 2 according to the present embodiment is different from the semiconductor device 1 in that a gate insulation layer 62 extends upwardly along sidewalls of a spacer 80. The gate insulation layer 62 is formed using a replacement metal gate (RMG) process. In addition, although not shown, the gate electrode 72 may also include at least one work function adjusting layer on the gate insulation layer 62 and also extending upwardly along sidewalls of the spacer 80.

Referring to FIG. 4, as in the semiconductor device 1, in the semiconductor device 2, the concentration of nitrogen atoms existing at a first interface S between an interface layer 50 and the gate insulation layer 62 is higher than that existing at a second interface R between the interface layer 50 and a channel layer 40. In addition, a majority of the nitrogen atoms present in interface layer 50 may exist at or adjacent the first interface S between the interface layer 50 and the gate insulation layer 62 whereas the region at and adjacent the second interface R between the interface layer 50 and the channel layer 40 may be substantially free of nitrogen atoms.

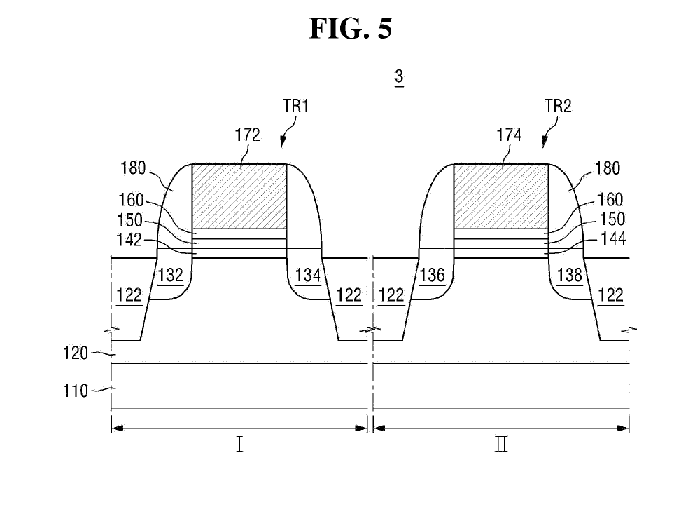

Next, another embodiment of a semiconductor device according to the inventive concept will be described with reference to FIG. 5.

The semiconductor device 3 has a base layer 120 that may be formed on a substrate 110, and a first region I and a second region II. The first region I may be an n-channel field effect transistor (NFET) region and the second region II may be a p-channel field effect transistor (PFET) region. In the illustrate example of this embodiment, therefore, a first transistor TR1 disposed on the first region I of the device 3 is an NFET, and a second transistor TR2 disposed on the second region II of the device is a PFET.

The substrate 110 may be made of at least one semiconductor material selected from the group consisting of Si, Ge, SiGe, GaP, GaAs, SiC and SiGeC. Alternatively, the substrate 110 may be a silicon on insulator (SOI) substrate.

The base layer 120 is of a group III-V compound to enhance the carrier mobility in the channel regions of the transistors TR1 and TR2. Examples of the group III-V compound are gallium arsenide (GaAs), gallium phosphide (GaP), indium arsenide (InAs), indium phosphide (InP), indium gallium arsenide (InGaAs), and indium gallium phosphide (InGaP).

An isolation layer 122, such as a shallow trench isolation (STI) layer, may be formed in the base layer 120 to define the channel regions in the base layer 120.

The first transistor TR1 includes first buffer layers 142 and 150, a gate insulation layer 160, a first gate electrode 172 and a first source 132 and a first drain 134 formed at opposite sides of the first gate electrode 172.

The first buffer layers 142 and 150 minimize gate leakage current which would otherwise be likely to occur if the gate insulation layer 160 made of a high-k material were to contact the base layer 120 made of a group III-V compound. Thus, the first buffer layers 142 and 150 enhance the reliability of the first transistor TR1.

The first buffer layers 142 and 150 are a first channel layer 142 and an interface layer 150 formed on the first channel layer 142, respectively. The first channel layer 142 may include a group IV element. For example, the first channel layer 142 may include Si. Also, the first channel layer 142 may provide the channel region of the first transistor TR1 alone or in combination with some of the base layer 120. Also, the first channel layer 142 may be used to form a strained channel of the first transistor TR1 because the material of the base layer 120 and the material forming the first channel layer 142 are different from each other.

Furthermore, the first channel layer 142 may be an epi layer. That is, the first channel layer 142 may be formed on the base layer 120 by an epitaxial growth process. Meanwhile, the first channel layer 142 may be relatively thin to prevent defects from being generated in the first channel layer 142 due to the stress applied from the base layer 120.

The interface layer 150 prevents a defective interface from existing between the first channel layer 142 and the gate insulation layer 160. In any case, the interface layer 150 is similar in terms of composition, characteristics, etc. to the interface layer 50 described above in connection with the embodiment of FIGS. 1 and 2. For example, the interface layer 150 may be of a low-k material having a dielectric constant (k) of 9 or less such as a silicon oxide layer (k≈4) or a silicon oxynitride layer (k≈4˜8 according to the contents of oxygen and nitrogen atoms). Alternatively, the interface layer 150 may be made of silicate, or may be a laminate of a combination of materials listed above.

Therefore, the interface layer 150 has the same effects and advantages as the interface layer 50 and will not be described in further detail for the sake of brevity.

Likewise, the first source 132, first drain 134, gate insulation layer 160 of high-k material, first gate electrode 172 and spacer 180 are similar to the source 32, drain 34, gate insulation layer 60, gate electrode 70 and spacer 80, respectively, of the embodiment of FIGS. 1 and 2 and will not be described in detail also for the sake of brevity. Note, however, in this example in which the first transistor TR1 is an NFET, the gate electrode 70 may have an n-type work function adjusting layer and a gate metal layer disposed on the n-type work function adjusting layer.

The second transistor TR2 on the second region II of the device 3 includes base layer 120, second buffer layers 144 and 150, a gate insulation layer 160, a second gate electrode 174 and a second source 136 and a second drain 138 formed at opposite sides of the second gate electrode 174.

The second buffer layers 144 and 150 prevent contact between the gate insulation layer 160 and the base layer 120. The second buffer layers 144 and 150 are a second channel layer 144 and an interface layer 150 formed on the second channel layer 144, respectively.

In this embodiment, the second channel layer 144 includes a group IV element different from that included in the first channel layer 142. For example, the first channel layer 142 includes Si, and the second channel layer 144 includes Ge.

The second channel layer 144 includes a group IV compound. In this embodiment, the first channel layer 142 consists of a group IV element, and the second channel layer 144 is of a group IV compound including the same group IV element as that in which forms the first channel layer 142. For example, the first channel layer 142 is an Si layer, and the second channel layer 144 is an SiGe layer.

The second channel layer 144 may provide the channel of the second transistor TR2 alone or in combination with some of the base layer 120. Furthermore, the second channel layer 144 may provide a strained channel of the second transistor TR2 because the material forming the base layer 120 and the material forming the second channel layer 144 are different from each other.

Also, the second channel layer 144 may be an epi layer. That is, the second channel layer 144 may be formed on the base layer 120 by an epitaxial growth process. Furthermore, the second channel layer 144 may be relatively thin so as to prevent defects from being generated in the second channel layer 144 due to the stress applied from the base layer 120.

The interface layer 150 of the second transistor TR2 is similar to the interface layer 50 of the embodiment of FIGS. 1 and 2 and therefore, will not be described in detail here for the sake of brevity.

Likewise, the second source 136, second drain 138, gate insulation layer 160 of high-k material, second gate electrode 174, and spacer 180 of the second transistor TR2 are similar to the source 32, drain 34, gate insulation layer 60, gate electrode 70 and spacer 80, respectively, of the embodiment of FIGS. 1 and 2 and will not be described in detail also for the sake of brevity.

However, in one example of this embodiment in which the second transistor TR2 is a PFET, the gate electrode 174 has a p-type work function adjusting layer, and a gate metal layer directly on the p-type work function adjusting layer. Alternatively, i.e., in another example, the gate electrode 174 has a p-type work function adjusting layer, an n-type work function adjusting layer on the p-type work function adjusting layer and a gate metal layer on the n-type work function adjusting layer. Furthermore, although the first and second transistors TR1 and TR2 of the embodiment shown in FIG. 5 are formed using a gate first process, the first and second transistors TR1 and TR2 may instead be formed using a replacement metal gate (RMG) process, so as to each have the form shown in FIG. 3.

As described above, in the semiconductor device 3, the gate insulation layer 160 formed of a high-k layer does not contact the base layer 120 formed of a group III-V compound; rather, the first channel layer 142 and the interface layer 150 are interposed therebetween. Thus, gate leakage current can be minimized.

Furthermore, in the case in which the interface layer 150 is formed of a nitride layer, for example, the concentration of nitrogen atoms existing at the interface between the interface layer 150 and the gate insulation layer 160 is higher than that existing at the interface between the interface layer 150 and each of the first and second channel layers 142 and 144. Preferably, hardly any nitrogen atoms are present at the second interface P between the interface layer 150 and each of the first and second channel layers 142 and 144, thereby preventing problems at the interface between interface layer 150 and each of the first and second channel layers 142 and 144 from deteriorating.

Accordingly, the reliability of the first and second transistors TR1 and TR2 can be improved.

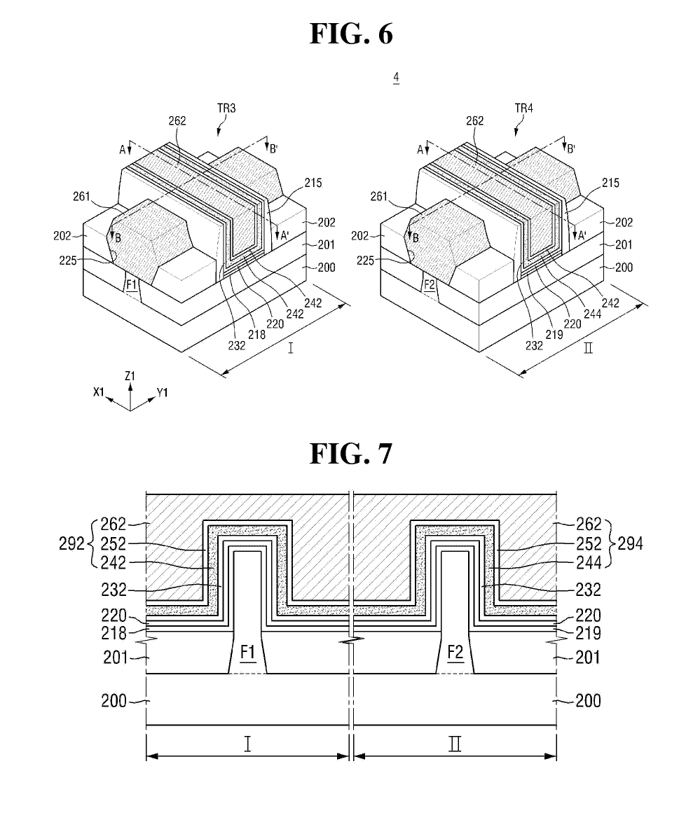

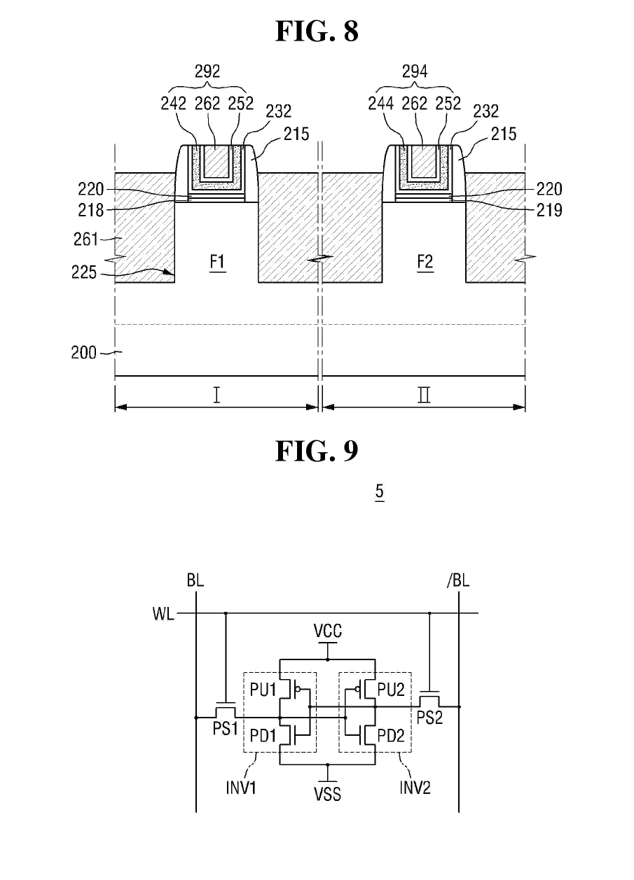

Next, another embodiment of a semiconductor device according to the inventive concept will be described with reference to FIGS. 6 to 8.

Basically, the semiconductor device 4 of FIGS. 6 to 8 is an application of the embodiment of the semiconductor device 2 of FIG. 3 applied to a fin-type transistor (FinFET); however, this embodiment is not limited to a FinFET configured based on the the semiconductor device 2 of FIG. 3. Rather, the FinFET of the semiconductor device 4 may employ the basic form of other types of semiconductor devices.

In any case, in this example, the semiconductor device 4 includes first and second fins F1 and F2, first and second gate electrodes 292 and 294, a recess 225, and a source/drain 261.

The first fin F1 is formed in a first region I of the device 4 and the second fin F2 is formed in a second region II of the device 4 and extend lengthwise in a second direction Y1. The fins F1 and F2 may be constituted by part of the base layer 200 and may be formed from an epitaxial layer grown from what was originally the base layer 200. An isolation layer 201 may cover side surfaces of the fins F1 and F2.

In this embodiment, the base layer 200 is of a group III-V compound. Examples of the group III-V compound include gallium arsenide (GaAs), gallium phosphide (GaP), indium arsenide (InAs), indium phosphide (InP), indium gallium arsenide (InGaAs), and indium gallium phosphide (InGaP). In any case, because the base layer 200 is of a group III-V compound, carrier mobility in the fins F1 and F2 is excellent.

A first transistor TR3 is formed at the top of the first fin F1 and a fourth transistor TR4 is formed at the top of the second fin F2. In this example, the third transistor TR3 includes a first channel layer 218, an interface layer 220, a gate insulation layer 232, a first work function adjusting layer 242, a barrier layer 252, and a gate metal 262, formed in the foregoing sequence on the first fin F1. Similarly, the fourth transistor TR4 includes a second channel layer 219, an interface layer 220, a gate insulation layer 232, a second work function adjusting layer pattern 244, a barrier layer 252, and a gate metal 262, formed in the foregoing sequence on the second fin F2.

The first and second channel layers 218 and 219 include respective group IV elements but are of different compositions. In one example of this, the first channel layer 218 consists of a group IV element and the second channel layer 219 consists of a group IV element different from that of the first channel layer 218. For example, the first channel layer 218 is of Si, and the second channel layer 219 is of Ge. Alternatively, the second channel layer 219 may be of a compound having a group IV element, whereas the first channel layer 218 consists of the same group IV element contained in the compound of the first channel layer 218. For example, the first channel layer 218 may consist of Si, and the second channel layer 219 may include SiGe.

Referring still to FIGS. 6-8, the first and second gate electrodes 292 and 294 cross the fins F1 and F2. In this respect, the first and second gate electrodes 292 and 294 extend longitudinally in a first direction X1 that intersects the second direction Y1. As shown, the first gate electrode 292 may include a first work function adjusting layer 242, a barrier layer 252, and a gate metal layer 262. The second gate electrode 294 may include a second work function adjusting layer 244, a barrier layer 252, and a gate metal layer 262.

The third transistor TR3 may be an N-type transistor, in which case the first work function adjusting layer 242 is an n-type work function adjusting layer. For example, the first work function adjusting layer 242 is a layer of material selected from the group consisting of TiAl, TiAlN, TaC, TaAlN, TiC, and HfSi. The first work function adjusting layer 242 may be formed to a thickness of, for example, 30 to 120 Å.

The fourth transistor TR4 may be a P-type transistor, in which case the second work function adjusting layer 244 is a p-type work function adjusting layer. For example, the second work function adjusting layer 244 includes a metal nitride layer and may be formed of at least one of TiN and TaN. In more detail, the second work function adjusting layer 244 may consist of a single layer made of TiN, or a dual layer consisting of a TiN lower layer and a TaN upper layer.

The gate metal layer 262 may comprise Al, in which case the barrier layer 252 interposed between the first and second work function adjusting layers 242 and 244 and the gate metal 262 prevents Al contained in the gate metal 262 from penetrating into the underlying gate insulation layer 232.

The recess 225 extends in the fins F1 and F2 at opposite sides of the first and second gate electrodes 292 and 294. Sides of the recess 225 are inclined with the recess 225 becoming gradually wider in a direction away from the base layer 200. As shown in FIG. 6, the recess 225 may be wider than the fins F1 and F2.

The source/drain 261 is formed in the recess 225. The source/drain 261 may be an elevated source/drain. That is, a top surface of the source/drain 261 may be higher than a bottom surface of an interlayer insulating layer 202. In addition, the source/drain 261 and the gate electrode 292 may be insulated from each other by the spacer 215.

As described above, in the semiconductor device 4 according to the inventive concept, the gate insulation layer 232 formed of a high-k layer and the base layer 200 formed of a group III-V compound do not contact each other; rather, the first channel layer 218 and an interface layer 220, and the second channel layer 219 and interface layer 220, are provided therebetween. Thus, gate leakage current can be minimized.

Furthermore, in the case in which the interface layer 220 is a nitride layer, the concentration of nitrogen atoms existing at an interface between the interface layer 220 and the gate insulation layer 232 is higher than that existing at an interface between the interface layer 220 and the first and second channel layers 218 and 219. Preferably, substantially no nitrogen atoms exist at the interface between the interface layer 220 and the first and second channel layers 218 and 219, thereby preventing problems at the interface between the interface layer 220 and each of the first and second channel layers 218 and 219.

Accordingly, the third and fourth transistors TR3 and TR4 are highly reliable.

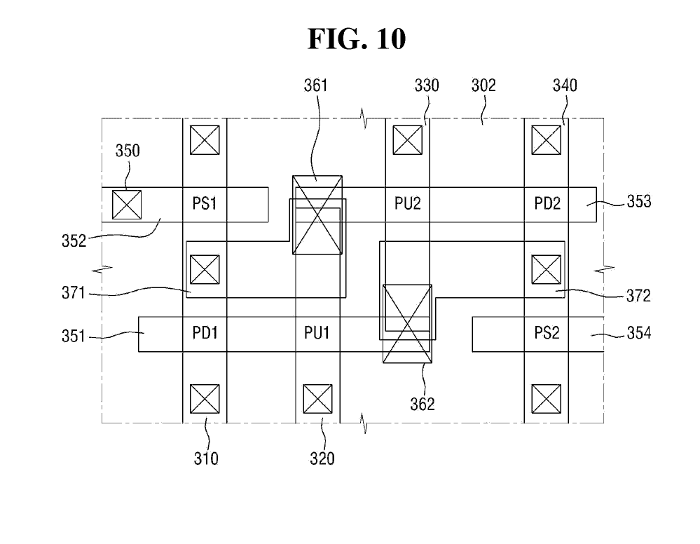

Next, another embodiment of a semiconductor device 5 according to the inventive concept will be described with reference to FIGS. 9 and 10.

The semiconductor device 5 includes a pair of inverters INV1 and INV2 connected in parallel between a power supply node Vcc and a ground node Vss, and a first pass transistor PS1 and a second pass transistor PS2 connected to output nodes of the respective inverters INV1 and INV2. The first pass transistor PS1 and the second pass transistor PS2 may be connected to a bit line BL and a complementary bit line/BL, respectively. Gates of the first pass transistor PS1 and the second pass transistor PS2 may be connected to word lines WL.

The first inverter INV1 may include a first pull-up transistor PU1 and a first pull-down transistor PD1 connected in series, and the second inverter INV2 may include a second pull-up transistor PU2 and a second pull-down transistor PD2 connected in series. The first pull-up transistor PU1 and the second pull-up transistor PU2 may be PFET transistors, and the first pull-down transistor PD1 and the second pull-down transistor PD2 may be NFET transistors.

In addition, in order to allow the first inverter INV1 and the second inverter INV2 to constitute a latch circuit, an input node of the first inverter INV1 is connected to the output node of the second inverter INV2, and an input node of the second inverter INV2 is connected to the output node of the first inverter INV1.

Still referring to FIGS. 9 and 10, a first active region 310, a second active region 320, a third active region 330 and a fourth active region 340, have the form of parallel strips spaced apart from one another and extending lengthwise in a given direction (up and down in FIG. 10). The second active region 320 and the third active region 330 may be shorter than the first active region 310 and the fourth active region 340.

In addition, the first gate electrode 351, the second gate electrode 352, the third gate electrode 353 and the fourth gate electrode 354 extend lengthwise in another direction (left and right in FIG. 10) so as to cross the first active region 310 to the fourth active region 340. In this respect, the first gate electrode 351 may completely cross the first active region 310 and the second active region 320 and may overlap part of a terminal end portion of the third active region 330. The third gate electrode 353 may completely cross the fourth active region 340 and the third active region 330 and may overlap part of a terminal end of the second active region 320. The second gate electrode 352 and the fourth gate electrode 354 cross the first active region 310 and the fourth active region 340, respectively.

As shown, the first pull-up transistor PU1 is defined around a region where the first gate electrode 351 and the second active region 320 cross each other, the first pull-down transistor PD1 is defined around a region where the first gate electrode 351 and the first active region 310 cross each other, and the first pass transistor PS1 is defined around a region where the second gate electrode 352 and the first active region 310 cross each other. The second pull-up transistor PU2 is defined around a region where the third gate electrode 353 and the third active region 330 cross each other, the second pull-down transistor PD2 is defined around a region where the third gate electrode 353 and the fourth active region 340 cross each other, and the second pass transistor PS2 is defined around a region where the fourth gate electrode 354 and the fourth active region 340 cross each other.

Although not shown, sources/drains are formed at opposite sides of the regions where the first to fourth gate electrodes 351 to 354 and the first to fourth active regions 310, 320, 330 and 340 cross each other, and a plurality of contacts 350 are formed.

In addition, a first shared contact 361 concurrently connects the second active region 320, the third gate line 353 and a wire 371. A second shared contact 362 concurrently connects the third active region 330, the first gate line 351 and a wire 372.

In this embodiment, the first pull-up transistor PU1 and the second pull-up transistor PU2 have the same configuration as any of the aforementioned P-type transistors according to the inventive concept. The first pull-down transistor PD1, the first pass transistor PS1, the second pull-down transistor PD2, and the second pass transistor PS2 have the same configuration as any of the aforementioned N-type transistors according to the inventive concept.

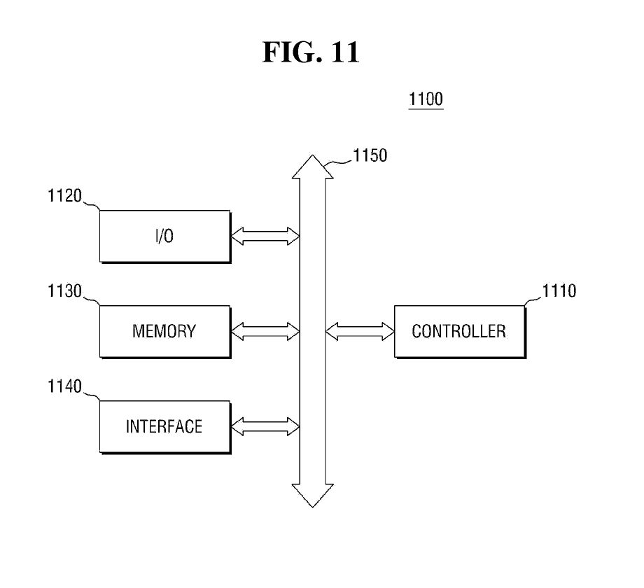

Next, an example of an electronic system including a semiconductor device according to the inventive concept will be described with reference to FIG. 11.

The electronic system 1100 includes a controller 1110, an input/output device (I/O) 1120, a memory device 1130, an interface 1140 and a bus 1150. The controller 1110, the I/O 1120, the memory device 1130, and/or the interface 1140 are connected to each other through the bus 1150. The bus 1150 provides a path through which data moves.

The controller 1110 may include at least one of a microprocessor, a digital signal processor, a microcontroller, and logic elements capable of functions similar to those of these elements. The I/O 1120 may include a keypad, a keyboard, a display device, and so on. The memory device 1130 may store data and/or code. The interface 1140 may perform functions of transmitting data to a communication network or receiving data from the communication network. The interface 1140 may be wired or wireless. For example, the interface 1140 may include an antenna or a wired/wireless transceiver. Although not shown, the electronic system 1100 may further include a high-speed DRAM and/or SRAM as the working memory for improving the operation of the controller 1110. Any of the semiconductor devices 1 to 5 according to inventive concept may be employed by the memory device 1130 or provided as part of the controller 1110 or the I/O 1120.

The electronic system 1100 is applicable to a personal digital assistant (PDA), a portable computer, a web tablet, a wireless phone, a mobile phone, a digital music player, a memory card, or any type of electronic device capable of transmitting and/or receiving information in a wireless environment.

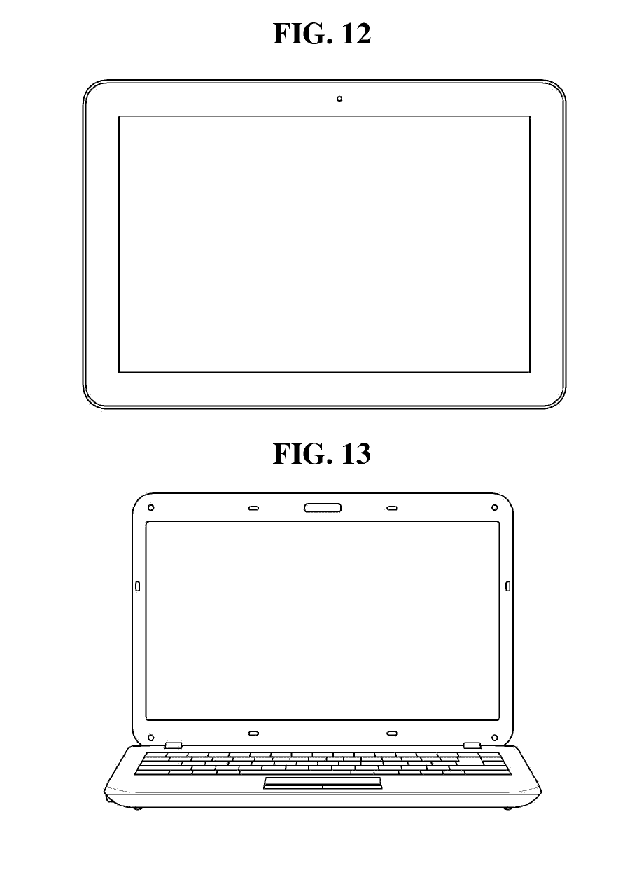

FIGS. 12 and 13 illustrate examples of electronic devices or products which can employ semiconductor devices according to the inventive concept. FIG. 12 illustrates a tablet PC, and FIG. 13 illustrates a notebook computer.

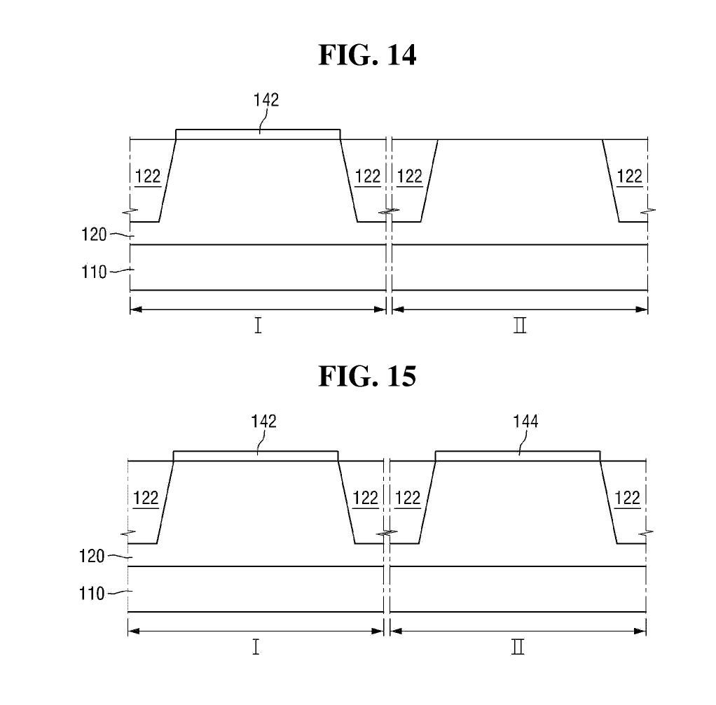

Next, an embodiment of a method of fabricating a semiconductor device according to the inventive concept will be described with reference to FIGS. 14 to 17.

First, referring to FIG. 14, a base layer 120 is formed a substrate 110, for example. Here, the base layer 120 may be formed on the substrate 110 by an epitaxial growth process. Next, an isolation layer 122, such as a shallow trench isolation (STI) layer, is formed in the base layer 120.

Next, a first channel layer 142 is formed on a region of the base layer 120 where the isolation layer 122 is not present. More specifically, a second region II of the base layer 120 is masked and the first channel layer 142, including Si, is formed on an exposed first region I of the base layer 120 by, for example, carrying out an epitaxial growth process.

Referring to FIG. 15, the first region I of the base layer 120 is masked and a second channel layer 144, including SiGe, is formed on the exposed second region II of the base layer 120 by, for example, carrying out an epitaxial growth process. Here, the first channel layer 142 and the second channel layer 144 are formed to be relatively thin so as to prevent defects from being generated in the first channel layer 142 and the second channel layer 144 due to the stress applied from the base layer 120.

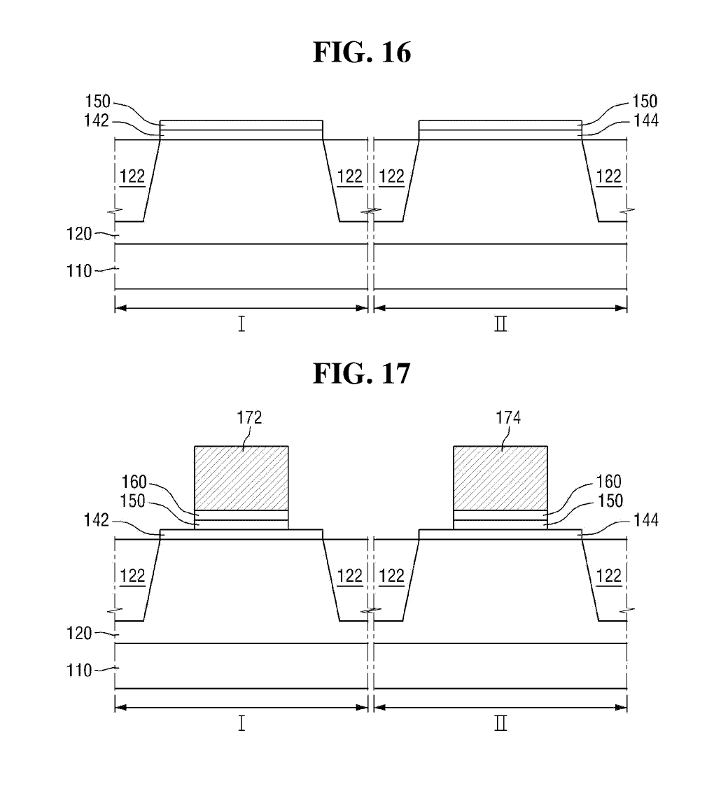

Next, referring to FIG. 16, an interface layer 150 is formed on the first and second channel layers 142 and 144. For example, a silicon oxide layer is first formed on the first and second channel layers 142 and 144 and the interface layer 150 is then formed on the silicon oxide layer including a silicon oxynitride layer by doping nitrogen atoms into the silicon oxide layer. Here, the doping is performed using UV or a similar technique so that scarcely any nitrogen atoms exist under the interface layer 150 and most of nitrogen atoms exist at the top of the interface layer 150.

Next, referring to FIG. 17, the gate insulation layer 160 and the first and second gate electrodes 172 and 174 are sequentially formed on the interface layer 150. Then, parts of the interface layer 150, the insulation layer 160, and the first and second gate electrodes 172 and 174 are removed, thereby exposing portions of the first and second channel layers 142 and 144.

As shown by FIG. 5, first and second sources 132 and 136 and the first and second drains 134 and 138 are formed by injecting impurities through exposed top surfaces of the first and second channel layers 142 and 144. Then, the spacer 180 is formed at opposite sides of the first and second gate electrodes 172 and 174.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A semiconductor device comprising:
a base layer of a compound of elements each being a group III or V element;
a channel layer disposed on the base layer and including a group IV element;
a nitride layer disposed on the channel layer;
a gate insulation layer disposed on the nitride layer; and
a gate electrode disposed on the gate insulation layer, and
wherein the concentration of nitrogen atoms existing at a first interface between the nitride layer and the gate insulation layer is higher than that existing at a second interface between the nitride layer and the channel layer.

2. The semiconductor device of claim 1, wherein the base layer has a first region and a second region, the channel layer has a first channel portion disposed on the first region and a second channel portion disposed on the second region, the first and second channel portions each comprise a group IV element, and the first channel portion comprises a group IV element different from any group IV element constituting the second channel portion.

3. The semiconductor device of claim 2, wherein the first channel layer comprises Si and the second channel layer comprises Ge.

4. The semiconductor device of claim 1, wherein the base layer includes a first region and a second region, the channel layer has a first channel portion disposed on the first region and a second channel portion disposed on the second region, the first channel portion comprises a first group IV element, and the second channel portion comprises the first group IV element and a second group IV element different than the first group IV element.

5. The semiconductor device of claim 4, wherein the first channel layer consists of Si and the second channel layer comprises SiGe.

6. The semiconductor device of claim 1, wherein a region adjacent and including the second interface is substantially free of nitrogen atoms.

7. The semiconductor device of claim 1, wherein the gate insulation layer is a layer of high-k material.

8. The semiconductor device of claim 7, wherein the high-k material includes at least one material selected from the group consisting of HfO₂, ZrO₂, Ta₂O₅, TiO₂, SrTiO₃ and BaTiO₃.

9. The semiconductor device of claim 1, wherein the compound is selected from the group consisting of GaAs, GaP, InAs, InP, InGaAs, and InGaP.

10. A semiconductor device comprising:
a base layer having a first region and a second region and comprising a compound of elements each being a group III or V element;
at least one first buffer layer disposed on the first region of the base layer and comprising a first channel layer;
at least one second buffer layer disposed on the second region of the base layer and comprising a second channel layer,
wherein the first channel layer comprises a group IV element, the second channel layer is of a compound including a group IV element, and the second channel layer has a composition different from that of the first channel layer; and
a high-k material layer disposed on the first and second buffer layers; and
a gate electrode disposed on the high-k material layer.

11. The semiconductor device of claim 10, wherein the at least one first buffer layer includes a nitride layer disposed on the first channel layer, and the at least one second buffer layer includes a nitride layer disposed on the second channel layer.

12. The semiconductor device of claim 11, wherein the concentration of nitrogen atoms existing at a first interface between the nitride layer and the high-k material layer is higher than that existing at a second interface between the nitride layer and the first and second channel layers.

13. The semiconductor device of claim 11, wherein the group IV element of the compound of the second channel layer is the same as that of the first channel layer.

14. The semiconductor device of claim 13, wherein the first channel layer consists of Si and the second channel layer comprises SiGe.

15. The semiconductor device of claim 10, comprising an n-channel field effect transistor (NFET) at the first region and a p-channel field effect transistor (PFET) at the second region.

16. A semiconductor device comprising:
a base of a compound of elements each being a group III or V element;
a channel layer contacting the base and including a group IV element;
a gate insulation layer of high-k material disposed on the channel layer;
an interface layer contacting the channel layer, whereby the interface layer is interposed between the channel layer and the gate insulation layer; and
a gate electrode disposed on the gate insulation layer, and
wherein an interface between the interface layer and the channel layer is substantially free of nitrogen atoms.

17. The semiconductor device of claim 16, wherein the interface layer comprises a layer of material doped with nitrogen atoms.

18. The semiconductor device of claim 16, wherein the high-k material includes at least one material selected from the group consisting of HfO₂, ZrO₂, Ta₂O₅, TiO₂, SrTiO₃ and BaTiO₃.

19. The semiconductor device of claim 16, wherein the compound is selected from the group consisting of GaAs, GaP, InAs, InP, InGaAs, and InGaP.

20. The semiconductor device of claim 4, wherein the channel layer consists of Si or comprises SiGe.
